(19) United States
(12) Patent Application Publication
(10) Pub. No.: US 2026/0223363 A1
(43) Pub. Date: Jul. 30, 2026

(54) SURFACE BASED EPITAXIAL GROWTH

(71) Applicant: Micron Technology, Inc., Boise, ID (US)

(72) Inventors: Yong Seung KIM, Boise, ID (US); Protyush SAHU, Boise, ID (US); Srinivas PULUGURTHA, Boise, ID (US); Ronald A. WEIMER, Boise, ID (US); Jeffery B. HULL, Boise, ID (US); Sachin DEV, Boise, ID (US); Abhishek KHANNA, Boise, ID (US)

(21) Appl. No.: 19/407,557

(22) Filed: Dec. 3, 2025

Related U.S. Application Data
(60) Provisional application No. 63/751,061, filed on Jan. 29, 2025.

(51) Int. Cl. H10B 12/00; G11C 11/4091

(52) U.S. Cl. CPC H10B 12/50; G11C 11/4091

(57) ABSTRACT

Implementations described herein relate to various structures, integrated assemblies, and memory devices. In some implementations, an integrated assembly includes a semiconductor substrate and an active region in the semiconductor substrate. The integrated assembly may include a first epitaxial structure on an upper surface of the semiconductor substrate, the first epitaxial structure having a first thickness in a first direction, and a second epitaxial structure on an upper edge of the semiconductor substrate, the second epitaxial structure having a second thickness in a second direction different than the first direction, where the second direction is oblique to the semiconductor substrate, and where the second thickness is less than the first thickness.

### CROSS-REFERENCE TO RELATED APPLICATION

This Patent application claims priority to U.S. Provisional Patent Application No. 63/751,061, filed on Jan. 29, 2025 entitled “SURFACE BASED EPITAXIAL GROWTH,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to surface based epitaxial growth.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a diagrammatic view of an example memory device.

FIG. 2 is a circuit diagram of an example memory cell.

FIG. 3 is a diagrammatic view of an example structure described herein. FIG. 3 includes a cross-sectional view of the example structure.

FIGS. 4A through 4G are diagrammatic views showing formation of the structure at example process stages of an example process of forming the structure.

FIG. 5 is a flowchart of an example method of forming an integrated assembly or memory device having surface based epitaxial growth.

### DETAILED DESCRIPTION

Some semiconductor manufacturing methods, such as methods to form DRAM devices, may include forming raised source/drain (RSD) structures that connect terminals of adjacent transistors (e.g., connect a source terminal of a first transistor to a drain terminal of a second transistor). An RSD structure may mitigate variations in the threshold voltage of the transistors. For example, forming an RSD structure may support improved control of the doping concentration of the RSD structure compared with other methods to form transistor terminals. Additionally, an RSD structure may provide a uniform junction depth for the source and/or drain terminals of the transistors, which may further reduce variability in the electrical characteristics of the terminals and thus may reduce the variability in threshold voltages.

In some cases, these transistors and RSD structures may be formed on isolated active regions of a semiconductor substrate. In such cases, epitaxially forming an RSD structure may also result in the formation of one or more pad structures on upper edges of the semiconductor substrate. However, if pad structures on adjacent active regions of the semiconductor substrate merge, the transistors may become shorted, thus decreasing the yield of the semiconductor manufacturing process.

Some implementations described herein enable surface based epitaxial growth to limit the thickness of pad structures. For example, as described in greater detail elsewhere herein, an epitaxial deposition process to form the RSD structures and the pad structures on a semiconductor substrate may use a process gas that includes a passivation gas and a silicon precursor gas. By modifying the ratio of the passivation gas to the silicon precursor gas, the growth rate of epitaxial structures may be modified based on the orientation of the epitaxial structures (e.g., relative to the crystal orientation of the semiconductor substrate). For example, increasing the ratio of the passivation gas to the silicon precursor gas may cause a difference in growth rates along the (100) direction (e.g., perpendicular to the surface of the semiconductor substrate) and the (111) direction (e.g., oblique to the surface of the semiconductor substrate). This difference in growth rates may result in a reduced thickness of a pad structure in the (111) direction relative to the thickness of an RSD structure in the (100) direction. Said another way, the thickness of the pad structure in the (111) direction may be less than the thickness of the RSD structure in the (100) direction. Additionally, this difference in growth rates may result in the RSD structure having a faceted and/or elliptical profile.

As a result, by modifying the ratio of the passivation gas to the silicon precursor gas, the distance between pad structures on adjacent active regions of the semiconductor substrate may be increased. This increased distance may reduce the likelihood of adjacent pad structures merging (e.g., bridging, coming into physical contact), and thus decrease the likelihood of manufacturing defects. Additionally, the increased distance between pad structures may improve heat dissipation by allowing more efficient thermal management. Further, the faceted and/or elliptical profile of the RSD structure may modify the capacitance between the RSD structure and gates of transistors (e.g., transistors of a sense amplifier). For example, the faceted profile may reduce the amount and/or geometry of semiconductor material between the RSD structure and the gate structure of a transistor, and thus reduce the capacitance between the RSD structure and the transistor. This lowered capacitance may improve operation of the transistor, such as by improving switching speed and/or reducing power consumption.

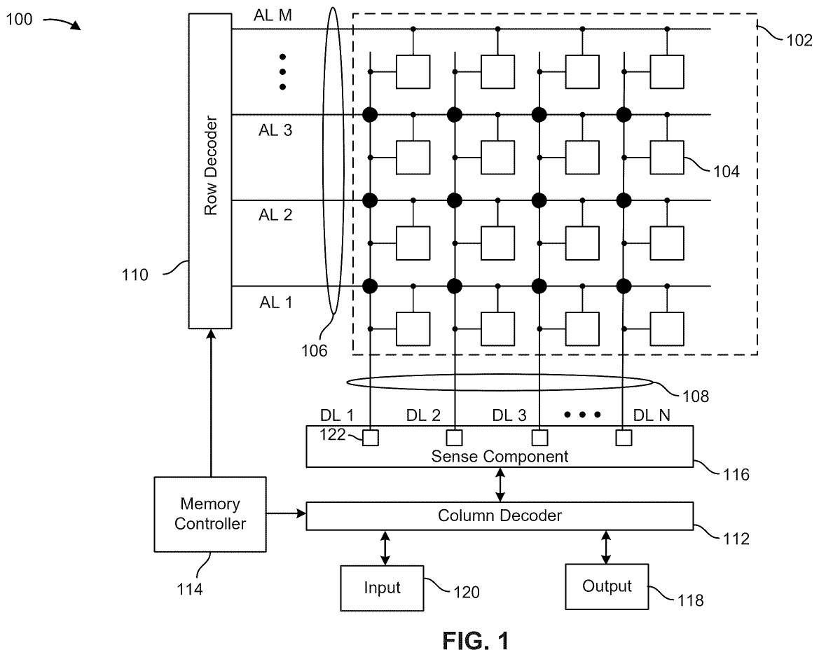

FIG. 1 is a diagrammatic view of an example memory device 100. The memory device 100 may include a memory array 102 that includes multiple memory cells 104. A memory cell 104 is programmable or configurable into a data state of multiple data states (e.g., two or more data states). For example, a memory cell 104 may be set to a particular data state at a particular time, and the memory cell 104 may be set to another data state at another time. A data state may correspond to a value stored by the memory cell 104. The value may be a binary value, such as a binary 0 or a binary 1, or may be a fractional value, such as 0.5, 1.5, or the like. A memory cell 104 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 104 by activating or selecting the appropriate access line 106 (shown as access lines AL 1 through AL M) and digit line 108 (shown as digit lines DL 1 through DL N). An access line 106 may also be referred to as a “row line” or a “word line,” and a digit line 108 may also be referred to as a “column line” or a “bit line.” Activating or selecting an access line 106 or a digit line 108 may include applying a voltage to the respective line. An access line 106 and/or a digit line 108 may comprise, consist of, or consist essentially of a conductive material, such as a metal (e.g., copper, aluminum, gold, titanium, or tungsten) and/or a metal alloy, among other examples. In FIG. 1, each row of memory cells 104 is connected to a single access line 106, and each column of memory cells 104 is connected to a single digit line 108. By activating one access line 106 and one digit line 108 (e.g., applying a voltage to the access line 106 and digit line 108), a single memory cell 104 may be accessed at (e.g., is accessible via) the intersection of the access line 106 and the digit line 108. The intersection of the access line 106 and the digit line 108 may be called an “address” of a memory cell 104.

In some implementations, the logic storing device of a memory cell 104, such as a capacitor, may be electrically isolated from a corresponding digit line 108 by a selection component, such as a transistor. The access line 106 may be connected to and may control the selection component. For example, the selection component may be a transistor, and the access line 106 may be connected to the gate of the transistor. Activating the access line 106 results in an electrical connection or closed circuit between the capacitor of a memory cell 104 and a corresponding digit line 108. The digit line 108 may then be accessed (e.g., is accessible) to either read from or write to the memory cell 104.

A row decoder 110 and a column decoder 112 may control access to memory cells 104. For example, the row decoder 110 may receive a row address from a memory controller 114 and may activate the appropriate access line 106 based on the received row address. Similarly, the column decoder 112 may receive a column address from the memory controller 114 and may activate the appropriate digit line 108 based on the column address.

Upon accessing a memory cell 104, the memory cell 104 may be read (e.g., sensed) by a sense component 116 to determine the stored data state of the memory cell 104. For example, after accessing the memory cell 104, the capacitor of the memory cell 104 may discharge onto its corresponding digit line 108. Discharging the capacitor may be based on biasing, or applying a voltage, to the capacitor. The discharging may induce a change in the voltage of the digit line 108, which the sense component 116 may compare to a reference voltage (not shown) to determine the stored data state of the memory cell 104. For example, if the digit line 108 has a higher voltage than the reference voltage, then the sense component 116 may determine that the stored data state of the memory cell 104 corresponds to a first value, such as a binary 1. Conversely, if the digit line 108 has a lower voltage than the reference voltage, then the sense component 116 may determine that the stored data state of the memory cell 104 corresponds to a second value, such as a binary 0. The detected data state of the memory cell 104 may then be output (e.g., via the column decoder 112) to an output component 118 (e.g., a data buffer). A memory cell 104 may be written (e.g., set) by activating the appropriate access line 106 and digit line 108. The column decoder 112 may receive data, such as input from input component 120, to be written to one or more memory cells 104. A memory cell 104 may be written by applying a voltage across the capacitor of the memory cell 104.

The memory controller 114 may control the operation (e.g., read, write, re-write, refresh, and/or recovery) of the memory cells 104 via the row decoder 110, the column decoder 112, and/or the sense component 116. The memory controller 114 may generate row address signals and column address signals to activate the desired access line 106 and digit line 108. The memory controller 114 may also generate and control various voltages used during the operation of the memory array 102.

The sense component 116 may include one or more sense amplifiers 122. Each sense amplifier 122 may be configured to obtain a signal from a respective digit line 108. A sense amplifier 122 may include one or more transistors, such as precharge transistors and/or equalizing transistors, to perform aspects of a sense operation to determine a state of a memory cell 104. In some implementations, the memory device 100 includes the structure 300 and/or an integrated assembly that includes the structure 300. For example, each sense amplifier 122 may include a respective structure 300 and/or a respective integrated assembly that includes the structure 300.

As indicated above, FIG. 1 is provided as an example. Other examples may differ from what is described with respect to FIG. 1.

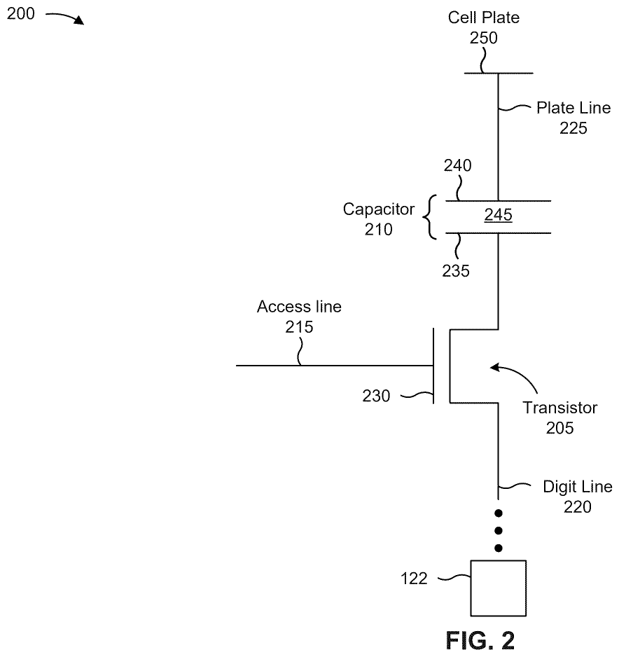

FIG. 2 is a circuit diagram of an example memory cell 200. In some implementations, the memory cell 200 is a ferroelectric memory cell. Alternatively, the memory cell 200 may be a linear dielectric memory cell or a paraelectric memory cell. As shown in FIG. 2, the memory cell 200 may include a transistor 205 (or another type of selection circuit) and a capacitor 210. The memory cell 200 may be accessed (e.g., written to, read from, and/or erased) using signals on a combination of lines that are coupled to the memory cell 200, shown as an access line 215 (sometimes called a “word line”), a digit line 220 (sometimes called a “bit line”), and a plate line 225.

The transistor 205 (sometimes called an access transistor) may include a gate 230. The capacitor 210 includes a bottom electrode 235 and a top electrode 240 separated by an insulator 245. In some implementations, the capacitor is a ferroelectric capacitor, and the insulator 245 is a ferroelectric insulator that comprises, consists of, or consists essentially of ferroelectric material. Alternatively, the capacitor may be a linear dielectric capacitor, and the insulator 245 may be a linear dielectric insulator that comprises, consists of, or consists essentially of linear dielectric material. Alternatively, the capacitor may be a paraelectric capacitor, and the insulator 245 may be a paraelectric insulator that comprises, consists of, or consists essentially of paraelectric material. When the access line 215 is activated (e.g., when a voltage is applied to the access line 215), the gate 230 coupled to the access line 215 may be activated. When the gate 230 is activated, the transistor 205 couples the digit line 220 to the bottom electrode 235 of the capacitor 210. A state of the memory cell 200 may then be written or read via the digit line 220.

The top electrode 240 of the capacitor 210 may be coupled to the plate line 225 and a cell plate 250. To write to (or program) the memory cell 200, the access line 215 may be activated, and a voltage may be applied across the capacitor 210 by controlling the voltage of the top electrode 240 (via the plate line 225 and/or the cell plate 250) and/or the bottom electrode 235 (via the digit line 220).

For a ferroelectric capacitor, the applied voltage creates an electric field, and the atoms in the ferroelectric material of the insulator 245 respond to the electric field to become arranged in a particular state (e.g., a particular orientation or polarization), which is representative of a data state (e.g., a logic “0” state or a logic “1” state). In some implementations, data may be stored using the capacitor 210 by controlling a voltage difference and/or a polarity difference of the capacitor 210 (e.g., of the insulator 245 between the bottom electrode 235 and the top electrode 240). For example, a voltage of the cell plate 250 and the digit line 220 may be controlled. In some implementations, a negative polarity of the insulator 245 as compared to the cell plate 250 results in a logic “0” state being stored in the capacitor 210, and a positive polarity of the insulator 245 as compared to the cell plate 250 results in a logic “1” state being stored in the capacitor 210. For a linear dielectric capacitor or a paraelectric capacitor, the cell plate 250 may be grounded, and the capacitor 210 may be charged by applying a voltage to the bottom electrode 235 via the digit line 220.

To read the memory cell 200 (e.g., a state stored by the capacitor 210), the access line 215 may be activated, and a voltage may be applied to the plate line 225. Applying a voltage to the plate line 225 may cause a change in the stored charge on the capacitor 210. The magnitude of the change in stored charge may depend on the stored state of capacitor 210 (e.g., whether the stored state is a logic “1” state or a logic “0” state). This may or may not induce a threshold change in the voltage of the digit line 220 based on the charge stored on the capacitor 210. The change in voltage or lack of change in voltage of the digit line 220 (or a magnitude of the change in voltage) may be used to determine the stored state of the capacitor 210. For example, if the change in voltage satisfies a threshold, then the read operation indicates that a first state was stored in the capacitor 210, whereas if the change in voltage does not satisfy the threshold, then the read operation determines that a second state was stored in the capacitor 210. In some cases, multiple threshold voltages may be used, such as when the capacitor is capable of storing more than two data states (e.g., for a multi-level cell, a triple-level cell, and so on).

The digit line 220 may be coupled to a sense amplifier 122. As part of reading the memory cell 200, the sense amplifier 122 may determine whether the change in voltage of the digit line 220 satisfies the threshold. For example, the sense amplifier 122 may include one or more transistors that support comparing the voltage of the digit line 220 to a reference voltage (e.g., using a differential amplifier). If the difference between the voltage of the digit line 220 satisfies a threshold, then the sense amplifier 122 may output a first state (e.g., a logic “1). Alternatively, if the change in voltage does not satisfy the threshold, then the sense amplifier 122 may output a second state (e.g., a logic “0”).

As indicated above, FIG. 2 is provided as an example. Other examples may differ from what is described with respect to FIG. 2.

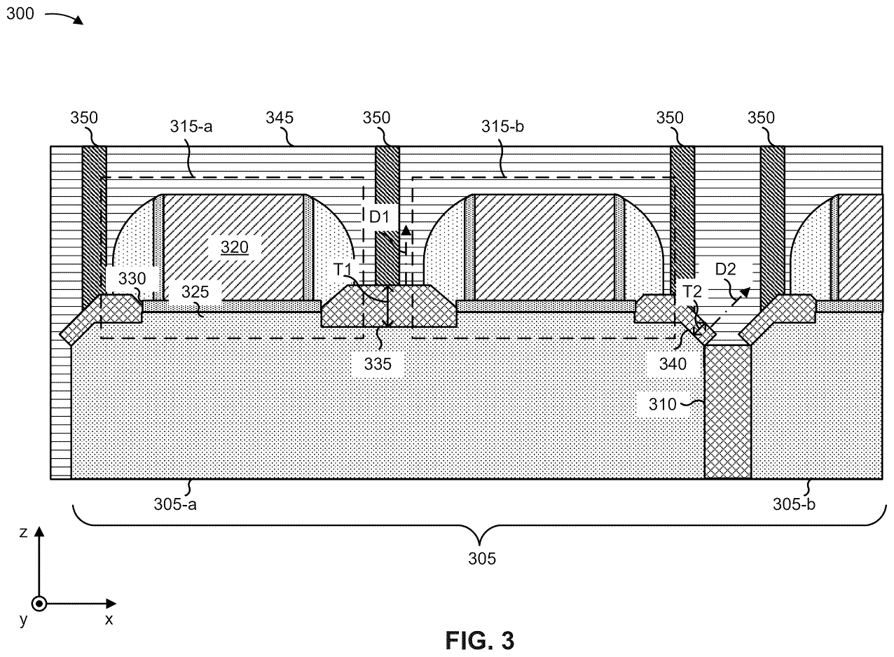

FIG. 3 is a diagrammatic view of an example structure 300. The structure 300 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). FIG. 3 illustrates a cross-sectional view of the structure 300.

As shown in FIG. 3, the structure 300 may include a semiconductor substrate 305. The semiconductor substrate 305 may be a bulk silicon substrate, a bulk silicon-germanium substrate, and/or a bulk silicon-carbon substrate, among other examples. In some examples, the semiconductor substrate 305 may be doped (e.g., lightly doped) with a p-type or an n-type impurity.

Various regions of the semiconductor substrate 305 may be electrically isolated from each other, and these electrically-isolated regions may be referred to as active regions of the structure 300. For example, an active region 305-a may be an electrically-isolated region of the semiconductor substrate in and/or on which one or more transistors are formed. As another example, an active region 305-b may be an electrically-isolated region of the semiconductor substrate in and/or on which one or more transistors are formed.

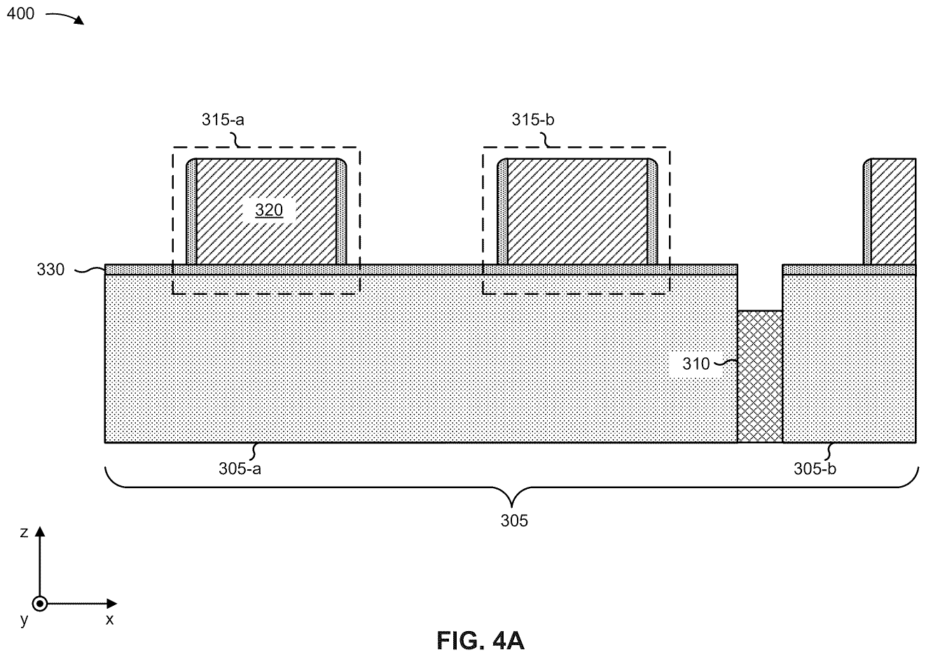

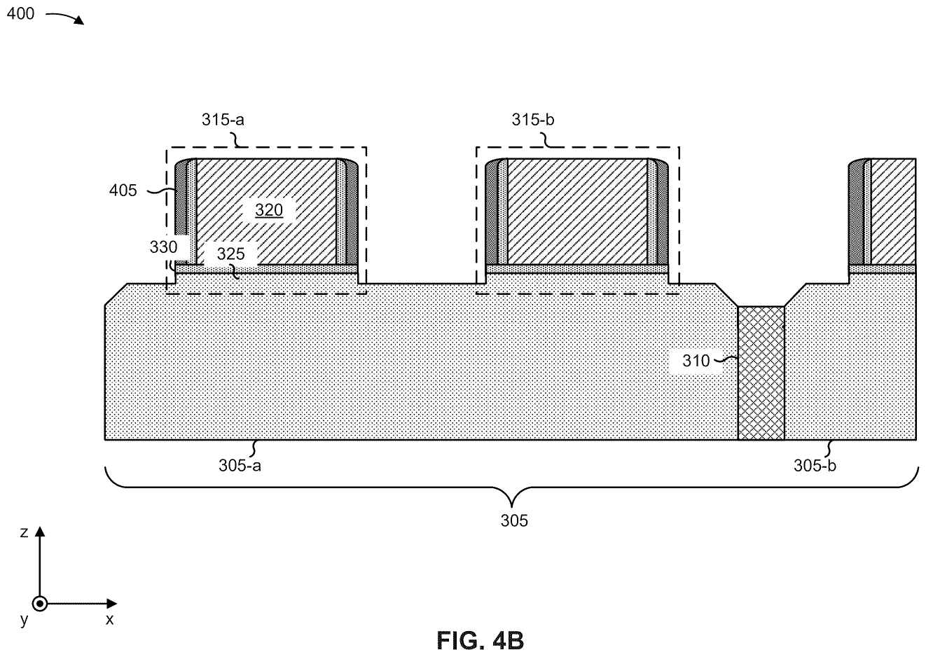

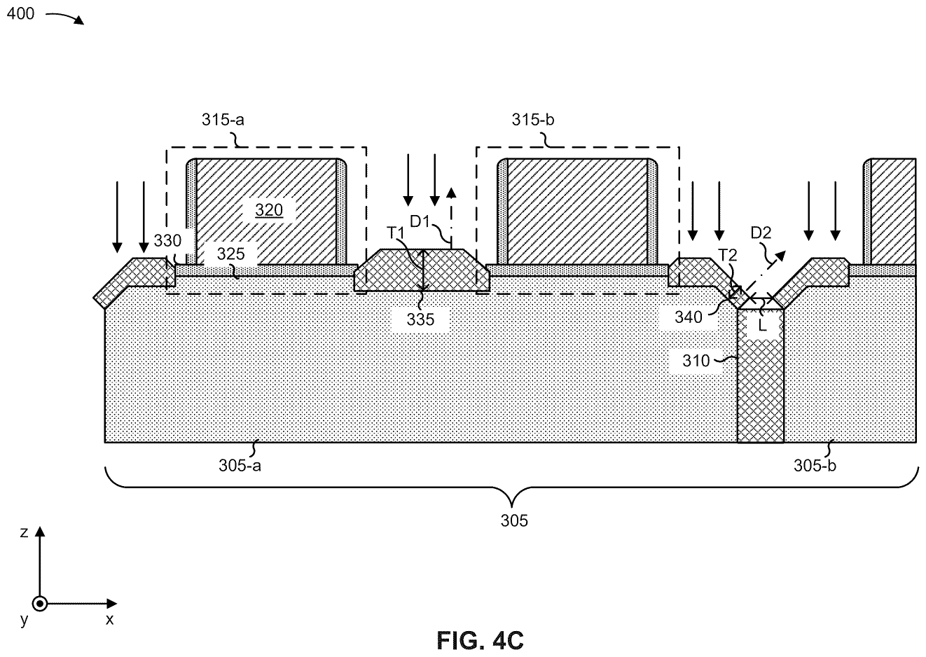

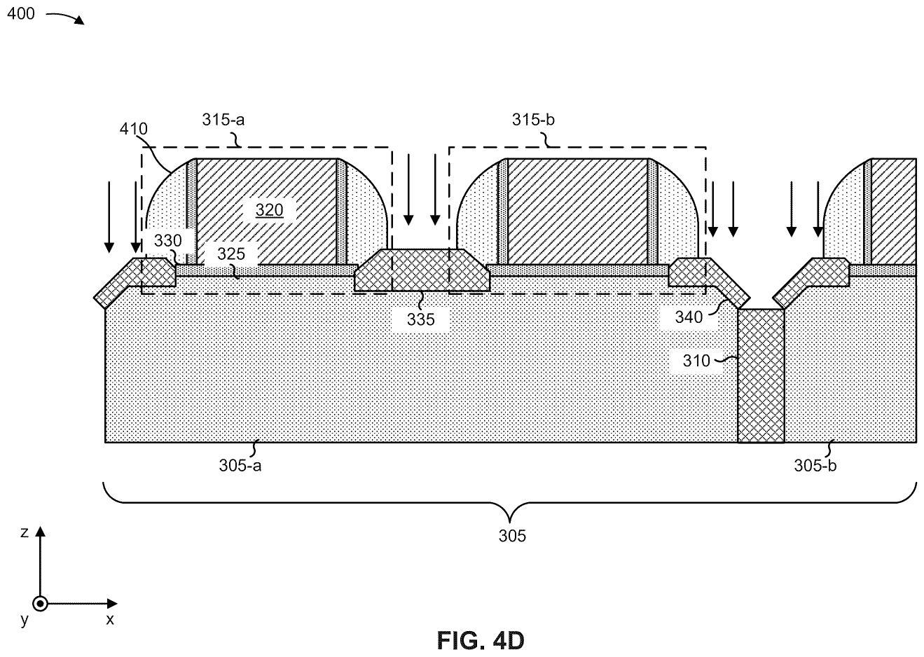

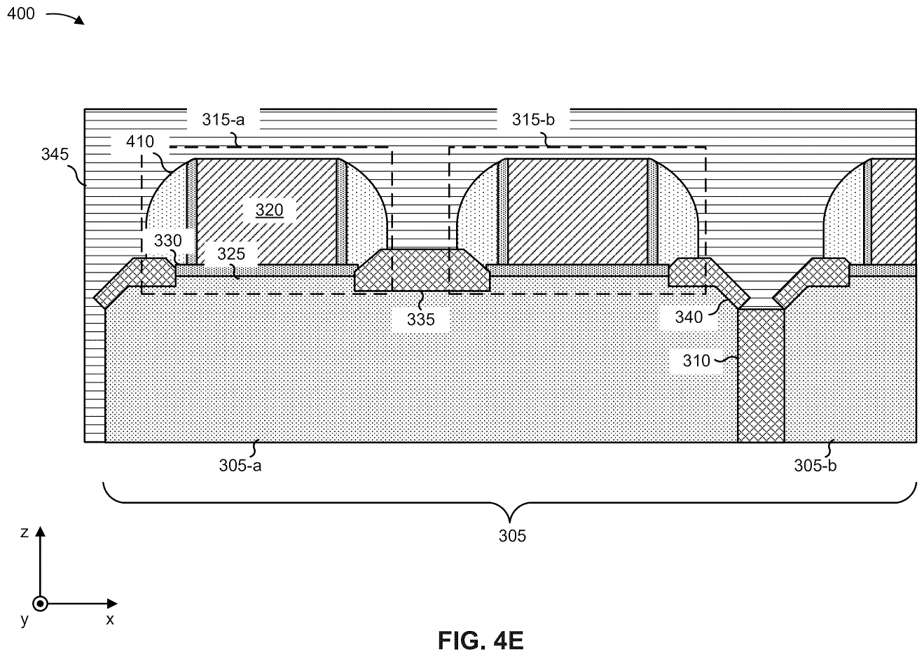

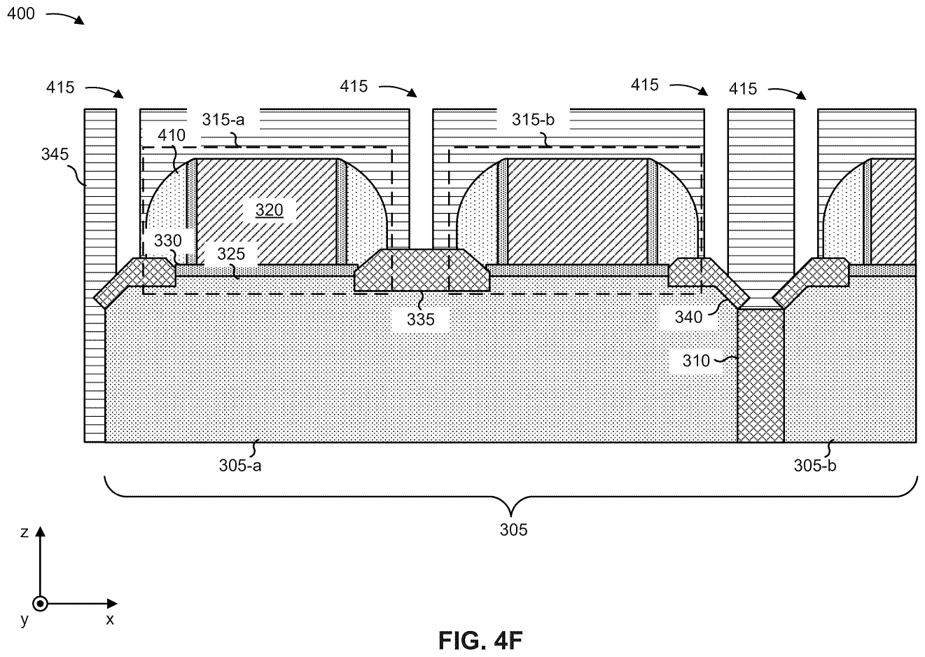

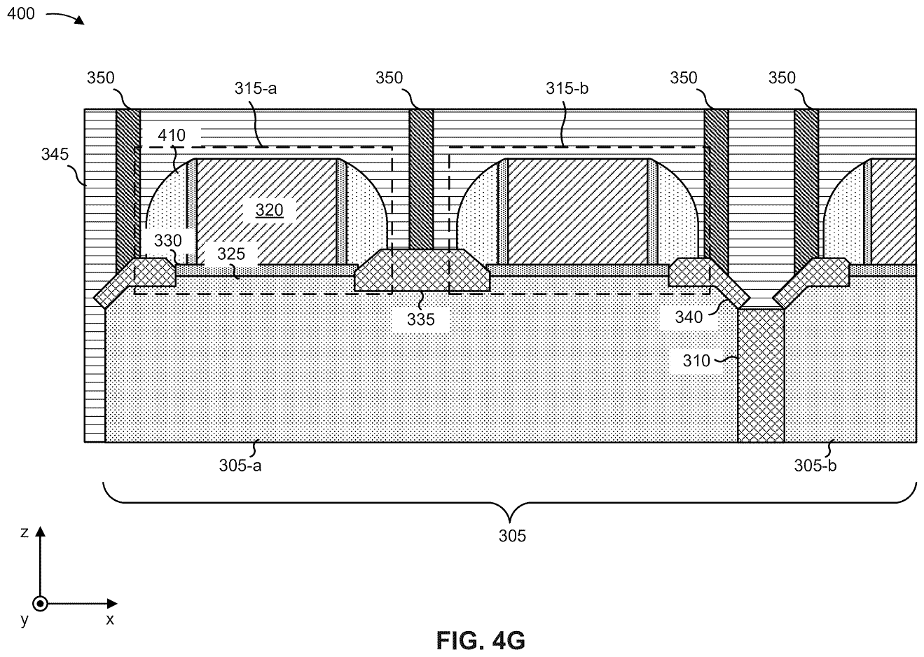

As described in greater detail in connection with FIG. 4A, an active region (e.g., the active region 305-a, the active region 305-b) may be formed by etching one or more trenches in the semiconductor substrate 305. Accordingly, an active region (e.g., the active region 305-a, the active region 305-b) may be a bulk silicon material, a bulk silicon-germanium material, and/or a bulk silicon-carbon material, among other examples. In some examples, an active region (e.g., the active region 305-a, the active region 305-b) may be doped (e.g., lightly doped) with a p-type or an n-type impurity.

The structure 300 may include one or more shallow-trench isolation (STI) regions between adjacent active regions (e.g., between the active region 305-a and the active region 305-b). In some cases, an STI region may include (e.g., may be completely or partially filled with) a dielectric material 310, such as silicon oxide and/or silicon nitride, among other examples. An STI region may isolate adjacent active regions 305-a and 305-b, which may reduce parasitic capacitance and leakage currents.

In some examples, the structure 300 may include one or more circuit components, such as one or more transistors 315, on respective upper surfaces of an active region of the semiconductor substrate 305. In some implementations, a transistor 315 may be an example of a metal-oxide-semiconductor transistor (MOSFET). For example, a transistor 315 may include a gate structure 320. The gate structure 320 may include a conductive material, such as tungsten, separated from a channel 325 of the transistor 315 by a gate oxide 330. As described in greater detail in connection with FIG. 4A, the channel 325 may be formed from semiconductor material of an active region of the semiconductor substrate 305. A transistor 315 may include source/drain regions on opposing sides of the channel 325 and on opposing sides of the gate structure 320. The source/drain regions may correspond to an RSD structure 335 and a pad structure 340. In some implementations, the one or more transistors 315 may be part of sensing circuitry of a memory device, such as a sense amplifier 122 of a memory device 100.

In some examples, transistors 315 on the same active region of the semiconductor substrate 305 may have variations in threshold voltages. For example, variations in the physical and/or electrical properties of the transistors 315-a and 315-b, such as depth and/or distribution of implanted dopants (e.g., due to manufacturing and/or material variations), may result in inconsistencies in threshold voltages across the transistors 315-a and 315-b. Such variations may degrade performance by causing non-uniform switching characteristics, increased power consumption, and reduced overall reliability.

The structure 300 may include one or more RSD structures 335 to address variations in threshold voltage, among other examples. An RSD structure 335 may be an epitaxial structure (e.g., a semiconductor structure grown using an epitaxial deposition process as described in greater detail elsewhere herein) that connects (e.g., electrically couples, physically extends between) terminals of adjacent transistors 315. For example, an RSD structure 335 may connect a source terminal of the transistor 315-a to a drain terminal of the transistor 315-b.

The RSD structure 335 may mitigate variations in the threshold voltage of the transistors 315-a and 315-b. For example, the epitaxial deposition process used to form the RSD structures 335 may support improved control of the doping concentration of the RSD structure 335, as described in greater detail in connection with FIG. 4C. Additionally, the RSD structure 335 may provide a uniform junction depth for the source and/or drain terminals of the transistors 315. This uniform junction depth may further reduce variability in the electrical characteristics of the terminals, and thus may reduce the variability in threshold voltages.

The RSD structure 335 may be formed by performing an epitaxial deposition process, such molecular beam epitaxy (MBE) and/or as metal-organic chemical vapor deposition (MOCVD). For example, forming the RSD structure 335 may include exposing the structure 300 to a gaseous mixture. The gaseous mixture may include a process gas that includes a silicon precursor gas, such as dichlorosilane (DCS), and a passivation gas, such as hydrogen chloride (HCl). The epitaxial deposition process may grow the RSD structure 335 in a direction D1 perpendicular to the upper surface of the active region 305-a. The upper surface of the semiconductor substrate 305 (and thus, the upper surfaces of the active regions 305-a and 305-b) may have a (100) crystal orientation. Accordingly, the direction D1 may be perpendicular to the (100) surface of the active region 305-a.

The epitaxial deposition process may be configured to grow the RSD structure 335 to a thickness T1 in the D1 direction (e.g., a length of the RSD structure 335 in the D1 direction), such as 20 nanometers (nm). For example, process parameters of the epitaxial deposition process, such as temperature, pressure, voltage bias, gas flow rate, and/or deposition duration, may be selected to achieve the thickness T1. The thickness T1 may enable the RSD structure 335 to mitigate variation in threshold voltage of the transistors 315.

The epitaxial deposition process may also form one or more pad structures 340 on upper edges of an active region of the semiconductor substrate 305. A pad structure 340 may be an epitaxial structure (e.g., a raised source/drain structure) grown from surface on or around an upper edge of an active region the semiconductor substrate 305. In some examples, the epitaxial deposition process may grow the pad structure 340 in a direction D2 that is oblique to the upper surface of the semiconductor substrate 305. For example, the upper edge of the semiconductor substrate 305 may include one or more (111) surfaces. Accordingly, the direction D2 may be perpendicular to the (111) surface of the active region 305-a of the semiconductor substrate 305. In such examples, the pad structure 340 may extend over the dielectric material 310 of the STI region.

The structure 300 may include a dielectric material 345 and one or more contact plugs 350. The dielectric material 345 may cover the gate structures 320, the RSD structure 335, and/or the pad structures 340. The dielectric material 345 may include or may be a backend dielectric layer of a backend region of the structure 300. The dielectric material 345 may include a low dielectric constant (low-k) dielectric material such as silicon dioxide (SiO₂) and/or another suitable low-k dielectric material. In some examples, the dielectric material 345 corresponds to a multiple-layer structure, in which low-k dielectric layers alternate with etch stop layers to provide etch selectivity when forming trenches in the dielectric material 345.

The one or more contact plugs 350 may provide electrical connection to the RSD structure 335 and/or the pad structures 340. In some examples, the one or more contact plugs 350 may be embedded within the dielectric material 345. The one or more contact plugs 350 may act as conductive pathways to allow electrical signals to pass between source/drain regions of the transistors 315 and other circuitry. One or more contact plugs 350 may extend alongside a gate structure 320 of a transistor 315 in the structure 300.

The contact plugs 350 may include vias, conductive pillars, conductive columns, and/or another type of vertically-elongated conductive structures. The contact plugs 350 may include one or more electrically conductive materials such as tungsten (W), cobalt (Co), ruthenium (Ru), copper (Cu), titanium (Ti), and/or tantalum (Ta), among other examples.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As indicated above, FIG. 3 is provided as an example. Other examples may differ from what is described with regard to FIG. 3.

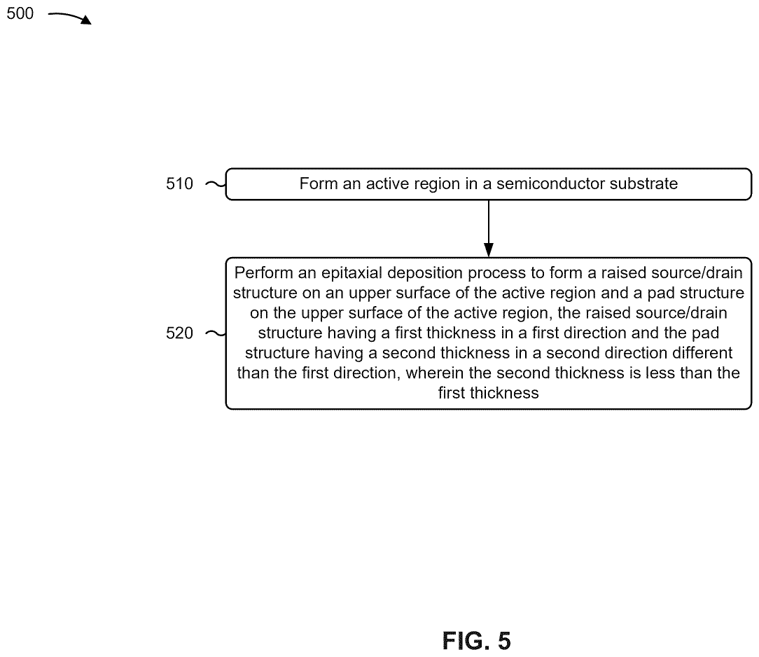

FIGS. 4A through 4G are diagrammatic views showing formation of the structure 300 at example process stages of an example process 400 of forming the structure 300. In some implementations, the example process described below in connection with FIGS. 4A through 4G may correspond to the method 500 and/or one or more blocks of the method 500, as described in greater detail in connection with FIG. 5. However, the process described below is an example, and other example processes may be used to form the structure 300, an integrated assembly that includes the structure 300, and/or one or more parts of the structure 300 and/or the integrated assembly.

As shown in FIG. 4A, the process 400 may include forming the one or more active regions in the semiconductor substrate 305. In some cases, the one or more active regions (e.g., active regions 305-a and 305-b) may be formed using shallow trench isolation (STI) techniques (e.g., the active regions may be electrically isolated by STI regions corresponding to the dielectric material 310). For example, the process 400 may include removing (e.g., etching) one or more portions of the semiconductor substrate 305 to form one or more trenches. A trench may expose one or more sidewalls of an active region of the semiconductor substrate 305. Said another way, the one or more trenches may define the active regions (e.g., the active regions 305-a and 305-b).

The process 400 may further include depositing the dielectric material 310 to fill the one or more trenches. Forming the dielectric material 310 may include performing a deposition process, such as High-Density Plasma (HDP) and/or Flowable Chemical Vapor Deposition (FCVD), among other examples. In some examples, after depositing the dielectric material 310, the process may include performing a planarization step (e.g., a chemical mechanical planarization (CMP) process) to mitigate surface irregularities and/or form flat upper surfaces on the semiconductor substrate 305 and/or the dielectric material 310. Additionally, or alternatively, the process 400 may include recessing the dielectric material 310, such that an upper surface of the dielectric material 310 may be below an upper surface of the semiconductor substrate 305.

The process 400 may include forming one or more transistors 315 in and/or on the semiconductor substrate 305. For example, transistors 315-a and 315-b may be formed in and/or on the active region 305-a of the semiconductor substrate 305. Forming the transistors 315 may include one or more deposition, patterning, and/or etching steps. For example, the process 400 may include forming a gate oxide 330 over an upper surface of the semiconductor substrate 305, such as by oxidizing the upper surface of the semiconductor substrate 305 (e.g., using thermal oxidation process). The process 400 may further include forming a conductive gate material, such as tungsten, over the gate oxide 330 using a CVD and/or physical vapor deposition (PVD) process, to form the gate structure 320. In some examples, the process 400 may include forming a dielectric material, such as an oxide and/or a nitride material, to create sidewall spacers of the gate structure 320.

As shown in FIG. 4B, the process 400 may include forming one or more dielectric spacers 405. Forming the one or more dielectric spacers 405 may include performing a conformal deposition process to deposit a dielectric material, such as silicon nitride and/or silicon oxide, among other examples. The conformal deposition process may include CVD and/or other conformal techniques to deposit the dielectric material over the gate structure 320 and on sidewalls of the gate structure 320. In some examples, after the conformal deposition, the process 400 may include performing an etching process to selectively remove the dielectric material from horizontal surfaces while leaving vertical sidewalls of dielectric material intact to define the dielectric spacers 405.

The process 400 may include removing portions of the active regions 305-a and 305-b to define channels 325 of the transistors 315. Forming the channels 325 may include performing an etching process to selectively remove material from the semiconductor substrate 305. The etching process may include a dry etching technique, such as reactive ion etching (RIE), to remove exposed portions of the semiconductor substrate 305.

As shown in FIG. 4C, the process 400 may include performing an epitaxial pre-clean operation. The epitaxial pre-clean operation may include preparing the surface of the semiconductor substrate 305, such as by removing residue or other contaminants. In some examples, the epitaxial pre-clean operation may remove the dielectric spacers 405 formed during previous process steps.

As further shown in FIG. 4C, the process 400 may include forming one or more RSD structures 335 and forming one or more pad structures 340. An RSD structure 335 may be formed by performing an epitaxial deposition process. For example, forming the RSD structure(s) 335 and the pad structure(s) 340 using the epitaxial deposition process may include exposing the structure 300 to a gaseous mixture that is deposited by CVD and/or another suitable deposition technique. The gaseous mixture may include a process gas that includes a silicon precursor gas, such as DCS, and a passivation gas, such as HCl. The epitaxial deposition process may include introducing the gaseous mixture into a reaction chamber and controlling one or more process parameters, such as the temperature of the reaction chamber and/or the flow rate of the silicon precursor gas and/or the passivation gas. For example, the flow rate may be configured such that the ratio of the passivation gas to the silicon precursor gas is greater than approximately 0.38:1. Additionally, the temperature range for the epitaxial deposition process may be between 750 degrees Celsius and 850 degrees Celsius.

The concentration of passivation gas in the gaseous mixture may modify respective growth rates of the RSD structure 335 and the pad structure 340. By way of illustration, the activation energy for silicon growth from silicon-hydrogen (Si—H) bonds may be lower compared to the activation energy for silicon growth from silicon-chlorine (Si—Cl) bonds. For example, the Si—H bond energy may be approximately 47 kcal/mol, while the Si—Cl bond energy may be about 90 kcal/mol. Thus, the chlorine-containing passivation gas may be used to passivate the surface of the semiconductor substrate 305 to control the growth rate of crystalline silicon on the surface of the semiconductor substrate 305. In particular, increasing the ratio of the passivation gas to and the silicon precursor gas may result in additional Si—Cl bonds present at the surface of the semiconductor substrate 305 during the epitaxial deposition process, and thus may result in an increased activation energy for semiconductor growth. This increased activation energy may reduce the growth rate of the RSD structure 335 and the pad structure 340.

Further, due to the difference in surface energy, step density, and/or adatom diffusion rates of the (100) and (111) surfaces of a semiconductor substrate 305, the change in growth rate in the direction D1 (e.g., the growth rate of a (100) surface) may be different than the change in growth rate in the direction D2 (e.g., the growth rate of a (111) surface). Accordingly, adjusting the ratio between the amount of the process gas and the amount of the etching gas for the epitaxial deposition process may result in a difference in the thickness T1 of the RSD structure 335 in the D1 direction and the thickness T2 of the pad structure 340 in the D2 direction.

The ratio of the passivation gas to the silicon precursor gas of the gaseous mixture of the epitaxial deposition process may be configured to reduce the thickness T2 while maintaining the thickness T1. Said another way, the ratio of the passivation gas to the silicon precursor gas may be selected to cause the thickness T2 to be less than the thickness T1. Further, reducing the thickness T2 of a pad structure 340 may increase the distance L (e.g., in the x-direction) between pad structures 340 on adjacent semiconductor substrate 305. For example, because pad structures 340 may grow epitaxially from the upper edges of the semiconductor substrate 305, reducing the thickness T2 of a pad structure 340 may also reduce the lateral (e.g., in the x-direction) growth of the pad structure 340. This reduction in lateral growth may result in a larger distance L between pad structures 340 on adjacent semiconductor substrate 305.

For example, a ratio of the passivation gas to the silicon precursor gas that is approximately 0.38:1 may result in a ratio of T2 to T1 of approximately 0.55:1. If the epitaxial deposition process is configured to form an RSD structure 335 having a thickness T1 of approximately 21.7 nm, then these ratios may result in a thickness T2 of a pad structure 340 being approximately 12 nm. Further, these ratios may result in the distance L between pad structures 340 on adjacent semiconductor substrate 305 being approximately 6.4 nm. As the ratio of the passivation gas to the silicon precursor gas is increased further, the ratio of T2 to T1 may further decrease, and the distance L may further increase. Table 1 shows the resulting thickness T1, the thickness T2, the ratio of T2 to T1, and the distance L for various ratios of passivation gas to silicon passivation gas.

TABLE 1

| | Passivation Gas to Silicon | | | |
|---|---|---|---|---|
| Passivation Gas Ratio | T1 (nm) | T2 (nm) | T2 to T1 Ratio | L (nm) |
| 0.38:1 | 21.7 | 12 | 0.55:1 | 6.4 |
| 0.50:1 | 20.5 | 9.4 | 0.46:1 | 12.9 |
| 2.00:1 | 11.3 | 2.1 | 0.19:1 | 28.3 |

By reducing the thickness T2 of a pad structure, the likelihood of adjacent pad structures 340 merging (e.g., bridging, coming into physical contact) may be reduced. Additionally, increasing the distance L between pad structures 340 of adjacent semiconductor substrate 305 may improve the electrical isolation between the semiconductor substrate 305. This improved isolation may result in reduced cross-talk and/or interference between circuit components, which may enhance signal integrity and/or reduce noise in the structure 300. Further, the increased distance L between pad structures 340 may reduce parasitic capacitance between adjacent semiconductor substrate 305, which may improve the switching speed of transistors 315. Additionally, the increased distance L between pad structures 340 may improve heat dissipation by allowing more efficient thermal management.

In some examples, the difference in growth rates along the D1 direction and the D2 direction may result in the RSD structure 335 having a faceted profile. For example, regions of RSD structure 335 aligned with the (100) surfaces may grow at a higher rate compared with regions of the RSD structure 335 aligned with other surfaces, such as the (111) surface and/or the (110) surface. This difference in growth rates may result in one or more angled upper surfaces (e.g., facets) of the RSD structure 335. Said another way, the thickness of the RSD structure 335 (e.g., the thickness in the D1 direction) may taper from the center of the RSD structure 335 to the outer edges of the RSD structure 335. Additionally, or alternatively, the different growth rates may result in the RSD structure 335 having a rounded or elliptical profile. For example, the reduced growth rate of regions aligned with the (111) and/or (110) surfaces may result in a smooth curve along the upper surface of the RSD structure 335, thus creating a rounded and/or elliptical shape.

The faceted and/or elliptical profile of the RSD structure 335 may modify the capacitance between the RSD structure 335 and respective gate structures 320 of the transistors 315-a and 315-b. For example, the faceted profile may reduce the amount and/or geometry of semiconductor material between the RSD structure 335 and the gate structure 320 of a transistor 315, and thus reduce the capacitance between the RSD structure 335 and the transistor 315. This lowered capacitance may improve operation of the transistor 315, such as by improving switching speed and/or reducing power consumption.

In some examples, the process 400 may include doping the RSD structures 335 and/or the pad structures 340. For example, the process 400 may include one or more doping operation, such as a lightly doped drain (LDD) operation and/or a halo implant operation. An LDD operation may include using ion implantation techniques to implant a concentration of dopants to the source and/or drain region of the transistors 315. A halo implant operation may include forming a ring (e.g., a “halo”) of dopant concentration around the source and/or drain regions of the transistors 315.

As shown in FIG. 4D, the process 400 may include forming one or more dielectric spacers 410. Forming the one or more dielectric spacers 410 may include performing a conformal deposition process to deposit a layer of dielectric material, such as silicon nitride and/or silicon oxide, among other examples. The conformal deposition process may deposit the layer of dielectric material over the gate structure 320 and/or on sidewalls of the gate structure 320. A subsequent etch operation may be performed to remove portions of the layer of dielectric material such that remaining portions of the layer of dielectric material on the sidewalls of the gate structure 320 corresponds to the dielectric spacers 410. In some examples, the etch operation is a vertical etch (e.g., an anisotropic etch) such as a plasma-based etch. In some examples, the conformal deposition process may dispose the dielectric spacers 410 over at least a portion of the RSD structures 335.

The process 400 may include one or more additional doping operations to dope the RSD structures 335. For example, the process 400 may include performing a source/drain extension (SDE) implant to introduce dopants into the RSD structures 335. The SDE implant may include introducing a low-energy, high-dose implant to form extensions of the source and/or drain regions. Additionally, or alternatively, the doping operation may include performing a pocket implantation to increase the doping concentration of the RSD structures 335.

As shown in FIG. 4E, the process 400 may include forming the dielectric material 345. Forming the dielectric material 345 may include depositing the dielectric material 345 over the structure to cover RSD structure 335, the one or more transistors 315, the pad structures 340, and/or the dielectric material 310. The dielectric material 345 may be deposited using various methods, such as CVD, atomic layer deposition (ALD), and/or physical vapor deposition (PVD). In some implementations, the dielectric material 345 may include multiple dielectric layers to achieve target insulating properties. These layers may include silicon oxide (SiO₂), silicon nitride (SiN), or other dielectric materials. After depositing the dielectric material 345, the process 400 may include performing a planarization step, such as CMP, to smooth the surface of the dielectric material 345.

As shown in FIG. 4F, the process 400 may include forming one or more trenches 415 in the dielectric material 345. Forming the one or more trenches 415 may include one or more patterning and/or etching processes to selectively remove portions of the dielectric material 345 to form the one or more trenches 415 for the contact plugs 350. For example, the process 400 may include a photolithography process to define the locations of the one or more trenches 415. The photolithography process may include forming a photoresist layer over the dielectric material 345 and exposing the photoresist layer to electromagnetic radiation (e.g., ultraviolet light, extreme ultraviolet light). The electromagnetic radiation may be used to transfer a trench pattern (e.g., a pattern in a photomask, a pattern in a reticle) to the photoresist layer. The trench pattern may be developed by removing exposed or unexposed portions of the photoresist layer (e.g., depending on the type of material used for the photoresist layer). The trench pattern in the photoresist layer may serve as a protective layer, exposing only the areas of the dielectric material 345 where the trenches 415 are to be formed.

After the photolithographic process, an etching process may be performed to remove portions of the dielectric material 345 in areas exposed through the trench pattern in the photoresist layer, such as by performing an RIE process. The etching process may expose upper surfaces of the RSD structure 335 and/or the pad structures 340. In some implementations, following the etching process, the photoresist layer may be removed through a photoresist removal process, such as by chemical stripping and/or plasma ashing.

As shown in FIG. 4G, the process 400 may include forming the one or more contact plugs 350. Forming the one or more contact plugs 350 may include depositing one or more layers of conductive material into the one or more trenches 415 in the dielectric material 345 to contact the RSD structure 335 and/or the pad structures 340. For example, the process 400 may include forming a conductive barrier layer. The conductive barrier layer may include a first layer of conductive material, such as titanium nitride (TiN). The process 400 may further include depositing a second conductive material, such as tungsten (W), titanium (Ti), and/or copper (Cu), to fill the one or more trenches and form the contact plugs 350.

In some examples, a salicidation process is performed in the trenches 415 prior to formation of the contact plugs 350. The salicidation process may include forming metal silicide layers on the RSD structure 335 and/or on the pad structures 340. The metal silicide layers may protect the exposed surfaces of the RSD structure 335 and/or of the pad structures 340 from oxidation, and may be included to reduce the contact resistance between the contact plugs 350 and the RSD structure 335 and/or the pad structures 340. The salicidation process may include depositing metal material on the surfaces of RSD structure 335 and/or on the pad structures 340 exposed in the trenches 415, and performing an annealing operation to cause the metal material to react with the semiconductor material of the RSD structure 335 and/or of the pad structures 340. The semiconductor material and the metal material may react to form a layer of metal silicide material, such as titanium silicide (TiSi), cobalt silicide (CoSi), and/or ruthenium silicide (RuSi), among other examples.

FIG. 5 is a flowchart of an example method 500 of forming an integrated assembly or memory device having surface based epitaxial growth. In some implementations, one or more process blocks of FIG. 5 may be performed by various semiconductor manufacturing equipment.

As shown in FIG. 5, the method 500 may include forming an active region of a semiconductor substrate (block 510). As further shown in FIG. 5, the method 500 may include performing an epitaxial deposition process to form a raised source/drain structure on an upper surface of the active region and a pad structure on the upper surface of the active region, the raised source/drain structure having a first thickness in a first direction and the pad structure having a second thickness in a second direction different than the first direction, where the second thickness is less than the first thickness (block 520).

The method 500 may include additional aspects, such as any single aspect or any combination of aspects described below and/or in connection with one or more other methods described elsewhere herein.

In a first aspect, performing the epitaxial deposition process includes exposing the semiconductor substrate to a gaseous mixture including a passivation gas and a silicon precursor gas, where a ratio of the passivation gas to the silicon precursor gas is greater than about 0.38:1.

In a second aspect, alone or in combination with the first aspect, the passivation gas includes hydrogen chloride and the silicon precursor gas includes dichlorosilane.

In a third aspect, alone or in combination with one or more of the first and second aspects, performing the epitaxial deposition process includes exposing, at a temperature in a range of 750 degrees Celsius to 850 degrees Celsius, the semiconductor substrate a gaseous mixture includes a passivation gas and a silicon precursor gas.

In a fourth aspect, alone or in combination with one or more of the first through third aspects, the method 500 includes forming, before the epitaxial deposition process, a first transistor on the semiconductor substrate, and forming, before the epitaxial deposition process, a second transistor on the semiconductor substrate.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the structure 300, an integrated assembly that includes the structure 300, any part described herein of the structure 300, and/or any part described herein of an integrated assembly that includes the structure 300. For example, the method 500 may include forming one or more of the parts of the RSD structures 335 and/or the pad structures 340.

In some implementations, a semiconductor device includes a semiconductor substrate; an active region in the semiconductor substrate; a first epitaxial structure on a portion of an upper surface of the semiconductor active region between two gate structures, the first epitaxial structure having a first thickness in a first direction; and a second epitaxial structure on another portion of the upper surface of the active region between one of the two gate structures and an STI region, the second epitaxial structure having a second thickness in a second direction different than the first direction, where the second direction is oblique to the semiconductor substrate, and where the second thickness is less than the first thickness.

In some implementations, a semiconductor device includes a semiconductor substrate; an active region in the semiconductor substrate; a first transistor on an upper surface of the active region; a second transistor on the upper surface of the active region; and an epitaxial structure on the upper surface of the active region, the epitaxial structure including one or more angled upper surfaces in a region between the first transistor and the second transistor.

In some implementations, a method includes forming an active region in a semiconductor substrate; and performing an epitaxial deposition process to form a raised source/drain structure on an upper surface of the active region and a pad structure on the upper surface of the active region, the raised source/drain structure having a first thickness in a first direction and the pad structure having a second thickness in a second direction different than the first direction, where the second thickness is less than the first thickness.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise. As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of”′ a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device, comprising:
a semiconductor substrate;
an active region in the semiconductor substrate;
a first epitaxial structure on a portion of an upper surface of the active region between two gate structures, the first epitaxial structure having a first thickness in a first direction; and
a second epitaxial structure on another portion of the upper surface of the active region between one of the two gate structures and a shallow trench isolation (STI) region, the second epitaxial structure having a second thickness in a second direction different than the first direction, wherein the second direction is oblique to the semiconductor substrate, and wherein the second thickness is less than the first thickness.

2. The semiconductor device of claim 1, further comprising:
a first transistor on the upper surface of the active region, the first transistor comprising a first gate structure of the two gate structures; and
a second transistor on the upper surface of the active region, the second transistor comprising a second gate structure of the two gate structures, wherein the first epitaxial structure couples a terminal of the first transistor to a terminal of the second transistor.

3. The semiconductor device of claim 2, wherein the first transistor and the second transistor are included in a sense amplifier of the semiconductor device.

4. The semiconductor device of claim 1, wherein a ratio of the second thickness and to first thickness is less than about 0.55:1.

5. The semiconductor device of claim 1, wherein the first thickness is about 20 nanometers and the second thickness is less than or equal to about 12 nanometers.

6. The semiconductor device of claim 1, further comprising:
another active region in the semiconductor substrate adjacent to the active region, wherein the STI region is between the active region and the other active region, and wherein the second epitaxial structure is over the STI region; and
a third epitaxial structure on an upper surface of the other active region, wherein the third epitaxial structure is over the STI region.

7. The semiconductor device of claim 6, wherein a distance between the second epitaxial structure and the third epitaxial structure is greater than about 6.4 nanometers.

8. The semiconductor device of claim 1, wherein the first direction is approximately perpendicular to a (001) plane of the semiconductor substrate and the second direction is approximately perpendicular to a (111) plane of the semiconductor substrate.

9. A semiconductor device, comprising:
a semiconductor substrate;
an active region in the semiconductor substrate;
a first transistor on an upper surface of the active region;
a second transistor on the upper surface of the active region; and
an epitaxial structure on the upper surface of the active region, the epitaxial structure comprising one or more angled upper surfaces in a region between the first transistor and the second transistor.

10. The semiconductor device of claim 9, wherein the epitaxial structure couples a terminal of the first transistor to a terminal of the second transistor.

11. The semiconductor device of claim 9, wherein the first transistor and the second transistor are included in a sense amplifier of the semiconductor device.

12. The semiconductor device of claim 9, further comprising:
a pad structure on an upper edge of the semiconductor substrate, wherein the epitaxial structure has a first thickness in a first direction and the pad structure has a second thickness in a second direction different than the first direction, wherein the second thickness is less than the first thickness.

13. The semiconductor device of claim 12, further comprising:
another active region in the semiconductor substrate adjacent to the active region;
a shallow trench isolation (STI) region between the active region and the other active region, wherein the pad structure is over the STI region; and
another pad structure on an upper edge of the other active region, wherein the other pad structure is over the STI region.

14. The semiconductor device of claim 13, wherein a distance between the pad structure and the other pad structure is greater than about 6.4 nanometers.

15. The semiconductor device of claim 12, wherein the first direction is perpendicular to a (001) plane of the semiconductor substrate and the second direction is perpendicular to a (111) plane of the semiconductor substrate.

16. A method, comprising:
forming an active region in a semiconductor substrate; and
performing an epitaxial deposition process to form a raised source/drain structure on an upper surface of the active region and a pad structure on the upper surface of the active region, the raised source/drain structure having a first thickness in a first direction and the pad structure having a second thickness in a second direction different than the first direction, wherein the second thickness is less than the first thickness.

17. The method of claim 16, wherein performing the epitaxial deposition process comprises:
exposing the semiconductor substrate to a gaseous mixture comprising a passivation gas and a silicon precursor gas, wherein a ratio of the passivation gas to the silicon precursor gas is greater than about 0.38:1.

18. The method of claim 17, wherein the passivation gas comprises hydrogen chloride and the silicon precursor gas comprises dichlorosilane.

19. The method of claim 16, wherein performing the epitaxial deposition process comprises:
exposing, at a temperature in a range of 750 degrees Celsius to 850 degrees Celsius, the semiconductor substrate to a gaseous mixture comprising a passivation gas and a silicon precursor gas.

20. The method of claim 16, further comprising:
forming, before the epitaxial deposition process, a first transistor on the upper surface of the active region; and
forming, before the epitaxial deposition process, a second transistor on the upper surface of the active region.
